(19) United States
(12) Patent Application Publication
(10) Pub. No.: US 2008/0007915 A1
(43) Pub. Date: Jan. 10, 2008

(54) Heat sink device for a heat generating element

(76) Inventor: Chao-Chuan Chen, Sijhih City (TW)

Correspondence Address: TROXELL LAW OFFICE PLLC, SUITE 1404, 5205 LEESBURG PIKE, FALLS CHURCH, VA, 22041, US

(21) Appl. No.: 11/480,985

(22) Filed: Jul. 6, 2006

(51) Int. Cl. H05K 7/20

(52) U.S. Cl. 361/701

(57) ABSTRACT

A heat sink device for a heat generating element is applied in a heat generating electronic element to divert and dissipate its waste heat in a direction. The heat sink device includes an L-shape rigid heat pipe, an end of which is assembled with a fin to form a heat sink end, and the other end of which is a bare tube heating end to be assembled with a heat absorption head through a clip board. An opposite surface of the clip board or the heat absorption head is provided with a concave rest or a cross rest to clip a heating end of the heat pipe, such that an orientation of the heat pipe can be adjusted by the clipping method.

### BACKGROUND OF THE INVENTION

(a) Field of the Invention

The present invention relates to a heat sink device for a heat generating element, and more particularly to a heat sink device which is used in an electronic circuit to divert a waste heat of an electronic element which can generate a high temperature, to a proper position with an adjustable orientation for dissipating the heat.

(b) Description of the Prior Art

It is necessary to effectively dissipate a waste heat generated from an electronic element installed in an electronic circuit, to prevent its electronic properties from being affected. More particularly, for a central processing unit which is intensively operating, a high temperature from operation should be dissipated effectively. A conventional method for dissipating heat from the heat generating electronic element is to install on its heating surface a cooling fin made by a metallic material capable of conducting heat and then to use a cooling fan to forcefully expel the conducted temperature. However, the drawn waste heat is still accumulated in a computer casing, and there is no apparent back pressure of convection except for cooling holes which face a streamline of axis of fan and are close to the casing.

Recently, due to a design requirement of space and efficiency, a heat pipe must be used to connect a heat sink end to a position which is easy for dissipating heat, in order to effectively expel the heat out of the casing, thereby forming a directional cooling path. An ordinary method for using the heat pipe is to use a U-shape pipe, an end of which is parallel connected to a heat absorption head, and the other end of which is parallel connected to the cooling fin, such that the U-shape heat pipe forms a three-dimensional fixation to connect with the heat absorption head and the cooling fin. In addition, the heat absorption head and the heat pipe are welded and fixed by a soldering method; therefore, a three-dimensional position of the cooling fin cannot be adjusted such that the conventional method can only be used in a single model design, and if it is not used in a specific casing, the waste heat will be accumulated in the computer.

### SUMMARY OF THE INVENTION

The primary object of present invention is to provide an L-shape rigid heat pipe, an end of which is connected to a cooling fin for forming a heat sink end, and the other end of which is fixed with a heat absorption head in a selectable orientation, such that the heat generated from the heat absorption head can be transmitted to a cooling fin through the heat pipe, and an orientation of the other end of heat pipe can be adjusted by swinging, using a relationship of the adjustable orientation between the heat pipe and the heat absorption head, to position the cooling fin at a proper three-dimensional position in a variable choice, for successfully expelling the heat.

Another object of the present invention is to install the heat absorption head with a clip board which uses a concave rest to fix a heating end of the heat pipe, wherein an interior of upper surface of the clip board or the heat absorption head is formed with a plurality of parallel concave rests or cross rests, so as to allow the heat pipe to be optionally installed at a side or to enable more than two heat pipes to be connected at the same time.

A third object of the present invention is to provide a plurality of concave rests or cross rests for the clip board or the heat absorption head, wherein more than two of them can be staggered in an cross-shape pattern.

A fourth object of the present invention is to install an interior the clip board with projected items which are protruded inward and aligned in a matrix, so as to form a positioning notch by using a separation of the projected items, thereby providing an optional positioning for the heating end of heat pipe.

A fifth object of the present invention is to fix the clip board with the heat absorption end by a fixing element, wherein the fixing element can use a C-shape elastic hook to achieve a fast assembling, and can correspond with a change of clipping pressure by using an elastic energy of the hook.

To enable a further understanding of the said objectives and the technological methods of the invention herein, the brief description of the drawings below is followed by the detailed description of the preferred embodiments.

### BRIEF DESCRIPTION OF THE DRAWINGS

FIG. 1 shows a perspective view of a fundamental structure of the present invention.

FIG. 2 shows a schematic view of a clip board which allows a heat pipe to change its direction, of the present invention.

FIG. 3 shows a side view of a heat pipe, a direction of which is changing, of the present invention.

FIG. 4 shows a schematic view of an embodiment of a heating end of a heat absorption head and a clip board of the present invention.

FIG. 5 shows a schematic view of another embodiment of a concave rest for a clip board of the present invention.

FIG. 6 shows a schematic view of a further embodiment of a concave rest of the present invention.

FIG. 7 shows a schematic view of a parallel concave rest implemented on a clip board of the present invention.

FIG. 8 shows a schematic view of a plurality of parallel concave rests implemented on a clip board of the present invention.

FIG. 9 shows a bottom view of concave rests which are staggered in a cross shape of the present invention.

FIG. 10 shows a schematic view of concave rests which are staggered in a # shape and implemented on a clip board of the present invention.

FIG. 11 shows a schematic view of another embodiment of a clip board of the present invention.

FIG. 12 shows a side view of a fixing element using a dried clipping method of the present invention.

FIG. 13 shows a schematic view of a heat absorption head which is provided with a positioning cross rest of the present invention.

### DETAILED DESCRIPTION OF THE PREFERRED EMBODIMENTS

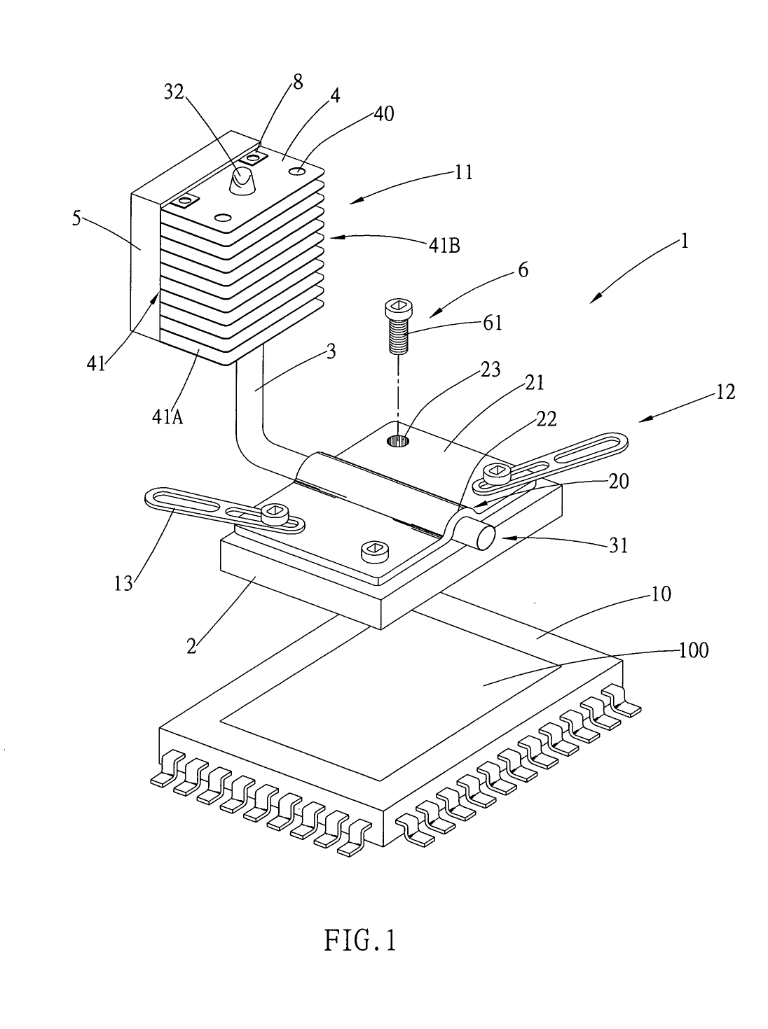

Referring to FIG. 1, a heat sink device 1 is composed of an L-shape rigid heat pipe 3, and end of which is connected to a heat absorption head 2 to form a heat absorption end 12, and the other end of which is connected to a cooling fin 4 to form a heat sink end 11. A bottom surface of the heat absorption head 2 is acted on a heating end 100 of a heat generating element 10, and a high temperature of the heat generating element 10 is transferred to the fin 4 through the heat pipe 3 to achieve a function of heat dissipation.

The fin 4 is provided with a plurality of overlapped sheets, a center of breadth of which is connected with a heat release end 32 of the heat pipe 3, and is able to effectively conduct out a high temperature from the heat release end 2. The fin 4 is composed of the plural sheets which are separated with one another vertically, with at least one diversion side 41 which is approximately in a flat and smooth shape. The flat and smooth diversion side 4 faces to a diversion device 5 which can be used to drive air flow to form directional heat dissipation. After the diversion fin 4 is assembled, a plurality of flat and smooth diversion sides 41, 41A, 41B can be further formed, which enables the diversion device 5 to perform directional heat dissipation and diversion, optionally along an outward orientation of a computer.

A clip board 21 is assembled on an opposite surface of the heat absorption head 2. The clip board 21 is installed with through-holes 23 through which are locked with fixing elements 6. The fixing elements 6 can be screws 61 which are used to lock the heat absorption head 2 through the through-holes 23, so as to lock the clip board 21 with the heat absorption head 2, wherein the clip board 21 is provided with a concave rest 22 along an axial direction of a heating end 31 of the heat pipe 3. An interior of the concave rest 22 is formed with a positioning notch 20 which provides a straddling of body part of the heating end 31. As the heating end 31 is enclosed by the positioning notch 20, after the clip board 21 is locked by the fixing elements 6, an inner surface of the positioning notch 20 can be used to lock an outer circumference of the heating end 31 for fixing.

The heat sink device 1 can be locked at any support position on a circuit board or a mechanism through a connection part 13, as long as the heat absorption end 2 has to effectively divert a waste heat of the heat generating element 10 to form the applicable heat absorption end 12, so as to expel the waste heat from the heat sink end 11 through the heat pipe 3.

The aforementioned diversion device 5 can be any device which can drive air flow, preferably a motor of fan. In addition, an L-shape adaptive part 8 is used to assemble the diversion device 5 and the overlapped cooling fin 4. The L-shape adaptive part 8 can be optionally fixed in a through-hole 40 of the fin 4 with a fixing part.

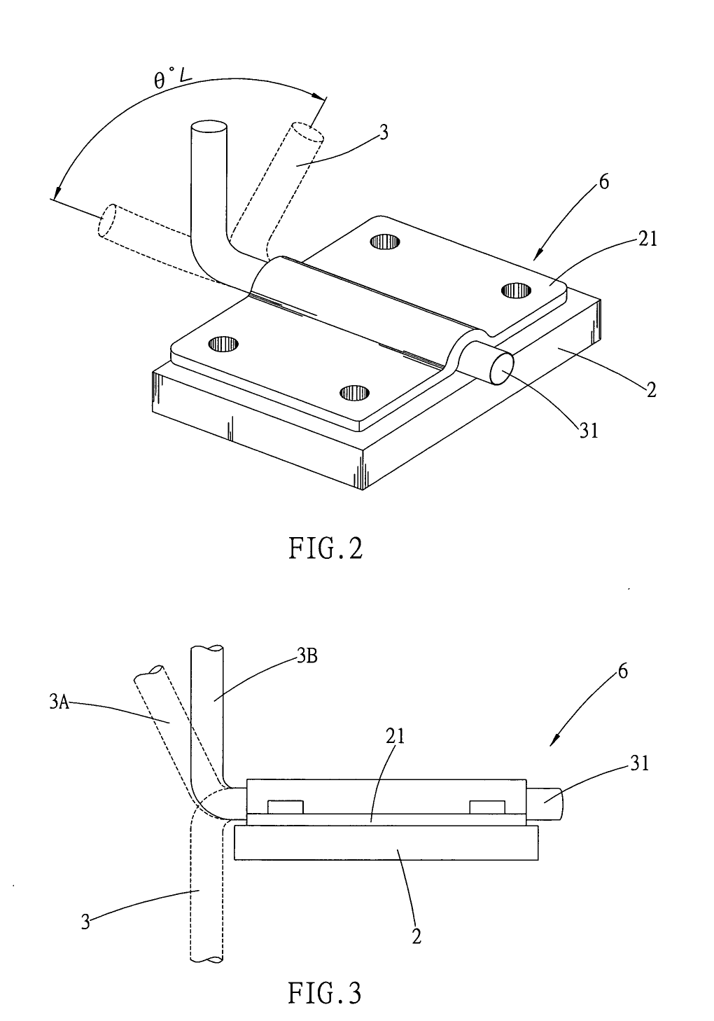

Referring to FIG. 2, the heating end 31 of heat pipe 3 is clipped on the heat absorption end 2 through the fixing elements 6 with the clip board 21; therefore, the fixing elements 6 can be operated in an opposite direction to release a clipping force between the clip board 21 and the heat absorption head 2. The heating end 31 will become a free state after being released, and thus a required orientation can be adjusted by optionally swinging a vertical rod of the L-shape heat pipe 3.

Referring to FIG. 3, the vertical rod of heat pipe 3 is operated by the fixing elements 6, such that a relaxation state is formed between the clip board 21 and the heat absorption head 2, and the vertical rod of heat pipe 3 is deflected downward by the heating end 31 along its line of axis.

Referring to FIG. 2 and FIG. 3, the present invention uses a lock and press relationship between the L-shape heat pipe 3 and the clip board 21, to provide a deflection at any orientation for the vertical rod of heat pipe 3, which changes relatively a three-dimensional position in any orientation of the aforementioned heat sink end 11 being exactly a tail end of the vertical rod of heat pipe 3.

The heat pipe 3 is in an L-shape, and its rotation angle can be larger or smaller than 90 degrees, so as to form a slant heat pipe 3A, 3B. By using different slant orientations, the heat pipe 3 can be applied with different orientations to different air openings of heat dissipation for different requirements of casings of different electronic devices. Basically, specifications of the heat absorption head 2, the clip board 21, and the heating end 31 are not changed, and an application in multiple orientations can be achieved only by changing a material of the heat pipe 3. If the heat pipe 3 is made by a plastic material, then its orientation can be available by directly bending with bare hands. However, it should be cautioned that a corner structure will not be damaged during bending.

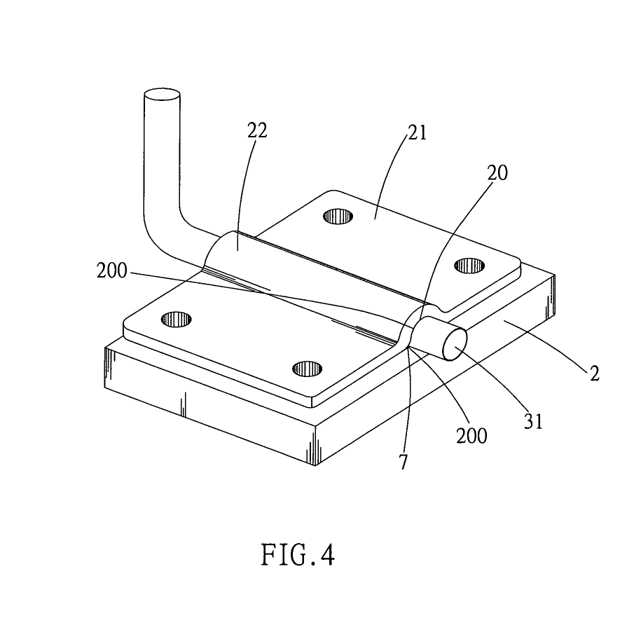

Referring to FIG. 4, the interior of concave rest 22 of the clip board 21 is formed with the notch 20. After the heating end 31 of a circular cross section is clipped, a gap of included angle 200 is formed between the internal surface of heating end 31 and the upper surface of heat absorption head 2. The gap of included angle 200 is filled with heat conduction glue which can assist the heat absorption head 2 to transmit the heat toward the heating end 31.

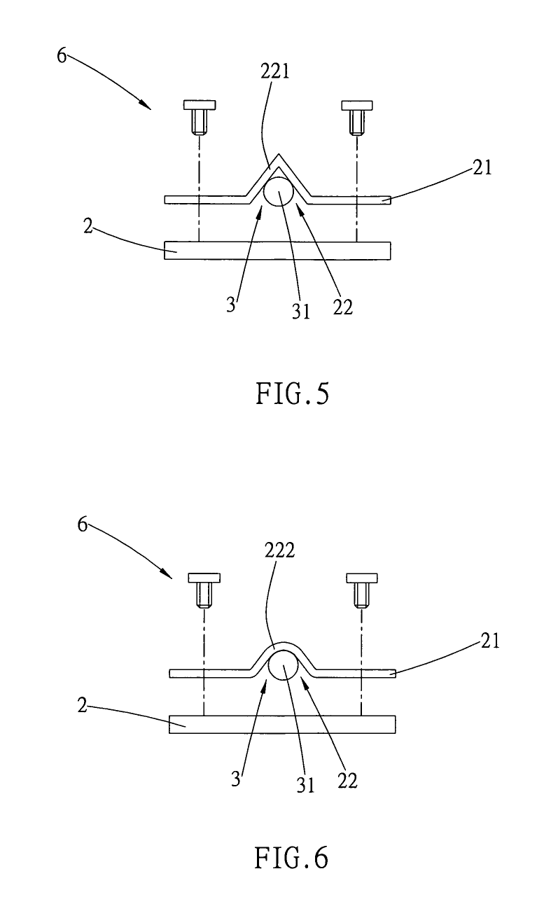

Referring to FIG. 5, a shape of cross section of the concave rest 22 of clip board 21 can be a V-shape slot 221, and an included angle of which is used to form a tangential effect with the heating end 31 of heat pipe 3. Through the fixing elements 6, the concave rest 22 is locked at the inner surface opposite to the heat absorption head 2, and two points which are pressed on tangential points of the heating end 31 are formed through the inner included angle of the V-shape slot 221. In addition, the upper surface of heat absorption head 2 is flat, which forms another tangential point with the heating end 31. Accordingly, three points are formed and fixed on cross sectional positions of the heating end 31 to prevent it from gliding in a radial direction.

Referring to FIG. 6, the concave rest 22 of clip board 21 can form an arc-shape slot 222, and an inner circumference of which can be used to form a large area to contact an outer circumference of the heating end 31 for increasing a frictional force. Similarly, a lower end of the concave rest 22 is connected with the flat and smooth upper surface of the heat absorption head 2 to form a single point of relative friction on an entire surface, which further can effectively prevent the heating end 31 from gliding in a radial direction.

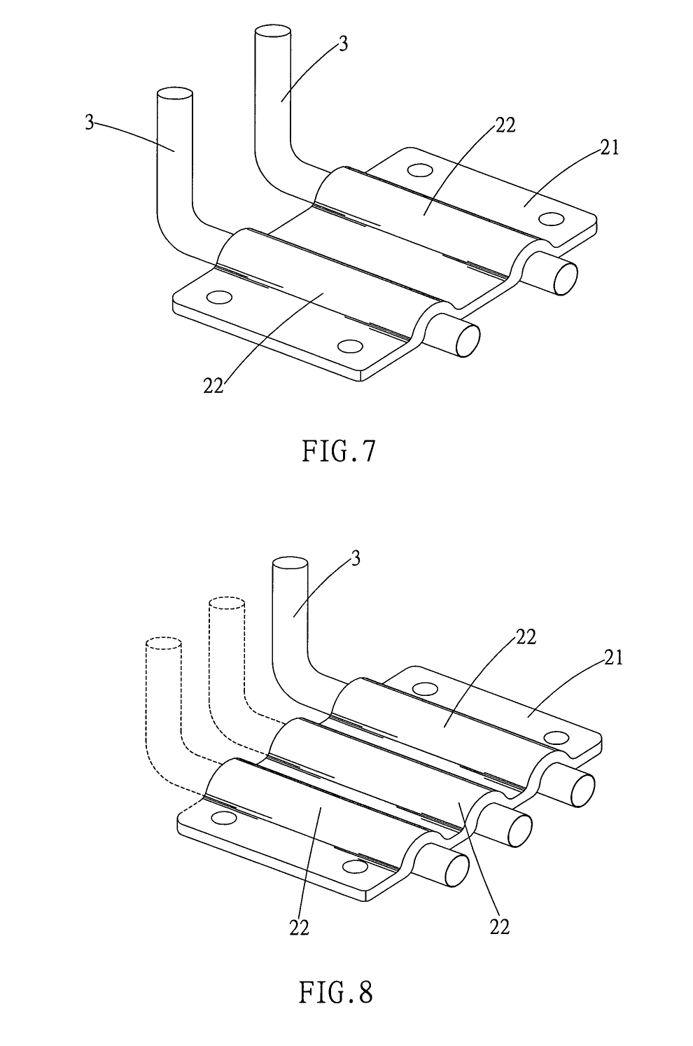

Referring to FIG. 7, a breadth of the clip board 21 is parallel installed with two concave rests 22 which can provide for a simultaneous connection of two heat pipes 3, or optionally provide for one heat pipe to be installed at one side.

Referring to FIG. 8, the breadth of clip board 21 is parallel installed with three or more than three concave rests 22 which can provide for a positioning and installation of the single heat pipe 3, optionally provide for a one-side installation of the single heat pipe 3, provide for the installation of one heat pipe 3 at the central concave rest 22, or simultaneously provide for the installation of the plural heat pipes 3 of corresponding quantities to form a larger capacity of heat dissipation.

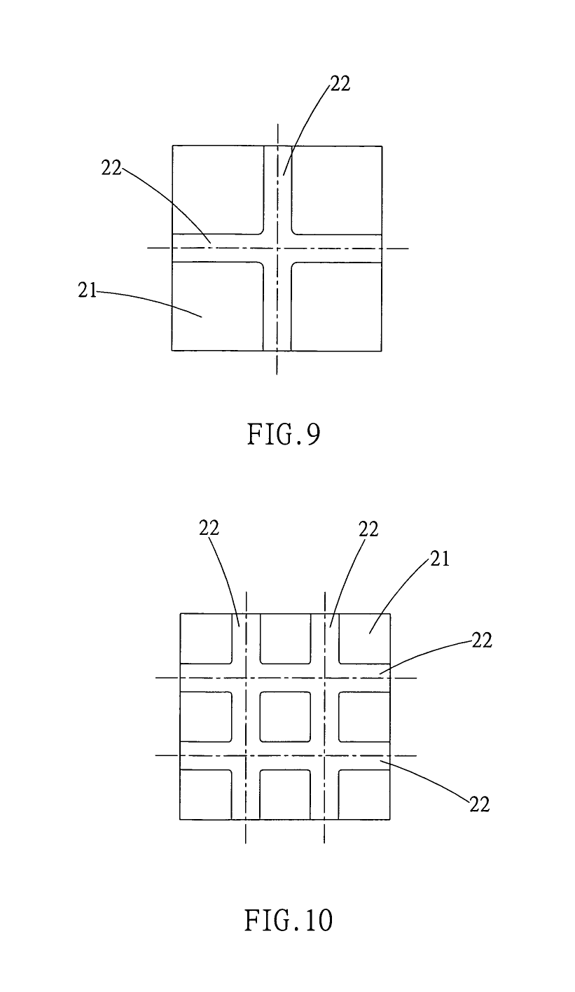

Referring to FIG. 9, the breadth of clip board 21 is opened with concave rests 22 which are staggered in a cross shape, such that the vertical or horizontal concave rests 22 can allow a single heat pipe to be connected in a vertical or horizontal orientation.

Referring to FIG. 10, the breadth of clip board 21 is formed with a plurality of concave rests 22 which are parallel staggered and are aligned in a # shape, so as to have a same function as that in FIG. 7, wherein the heat pipe can be optionally installed at a proper side or in a plurality of orientations.

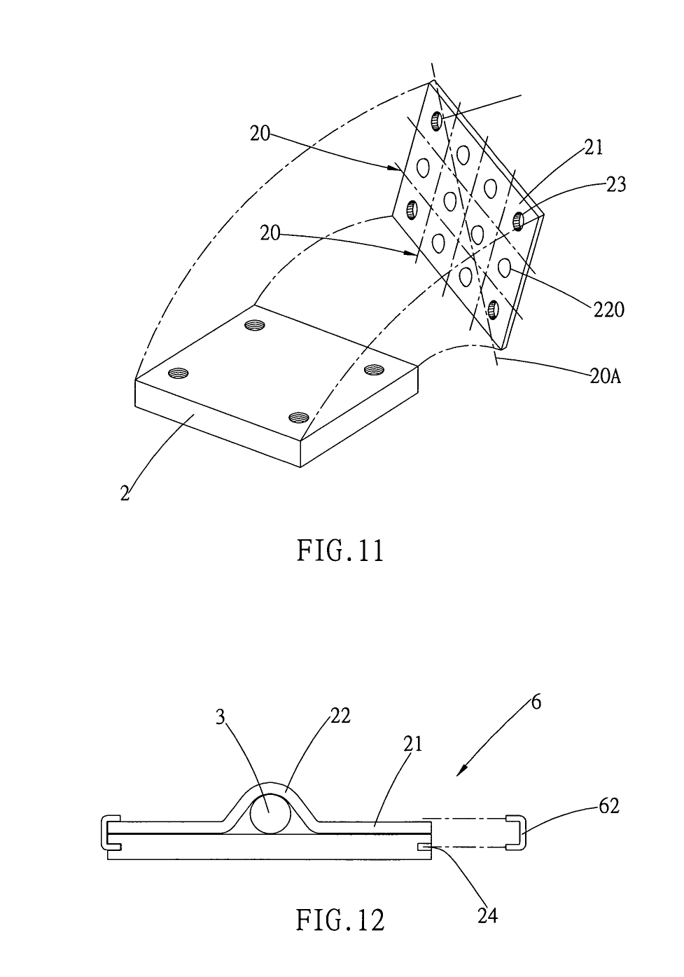

Referring to FIG. 11, in addition to that an inner surface of the clip board 21 corresponding to the heat absorption head 2 is provided with the through-holes 23, a plurality of projected items 220 are aligned in a matrix. The positioning notch 20 can be formed between a separation of the projected items 220, to provide for an optional positioning and installation of the aforementioned heat pipe. After positioning, a clipping is formed between the clip board 21 and the heat absorption head 2, and the positioning notch 20 is formed by the separation of projected items 220 to achieve a linear fixation, wherein a line of axis of the positioning notch 20 can be in a slant direction under a condition of effective alignment of the projected items 220.

Referring to FIG. 12, the clip board 21 clips the heat pipe 3 through the concave rest 22, and a hook slot 24 is located at a side of the heat absorption head 2, such that an end of a C-shape hook element 62 can be clipped to the hook slot 24, and the other end of the C-shape hook element 62 can be clipped to a surface of the clip board 21, thereby assembling the clip board 21 with the heat absorption head 2 by a clipping method.

The C-shape hook 62 can be an elastic body, and is able to correspondingly absorb a change of gap size between the clip board 21 and the heat absorption head 2 by its elastic energy. More particularly, during a process of swelling or cooling of structural element, the elastic effect of the C-shape hook element 62 can be used to absorb a displacement of swelling, so as to ensure an effective fixation of the heat pipe 3.

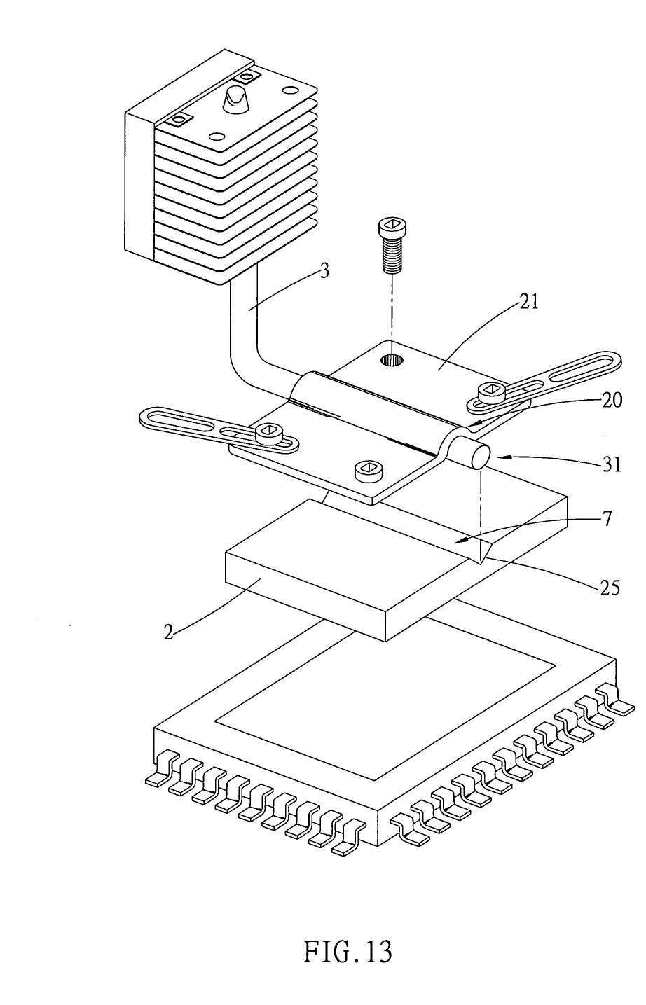

Referring to FIG. 13, the clip board 21 is provided with the positioning notch 20 which faces an upper surface of the heat absorption head 2 to clip the heating end 31 of heat pipe 3. Correspondingly, the upper surface of heat absorption head 2 can be further opened with a concaved cross rest 25 which provides for the heating end 31 to be straddled by burying shallowly. After being clipped by the clip board 21, the heating end 31 can be positioned in a radial direction, and can have a larger radial frictional force through the corresponding cross rest 25.

The aforementioned cross rest 25 is used by the clip board 21 to assemble the heat pipe 3, and an outer circumference of heating end 31 of heat pipe 3 is enclosed to leave a gap which can be filled with a heat conduction glue 7, as shown in FIG. 4.

The implementation of aforementioned cross rest 25 can be similarly implemented on corresponding positions of concave rests 22 according to different orientations or quantities, as shown in FIGS. 7 to 10, or FIGS. 11 to 12. In principle, a mechanical strength and efficiency of heat transmission of the heat absorption head 2 should be maintained, and it is not proper to open a plurality of surplus cross rests 25 on the upper surface of heat absorption head 2, so as to ensure safety and a good heat transmission effect.

It is of course to be understood that the embodiments described herein is merely illustrative of the principles of the invention and that a wide variety of modifications thereto may be effected by persons skilled in the art without departing from the spirit and scope of the invention as set forth in the following claims.

What is claimed is:

1. A heat sink device for a heat generating element, which is applied in an electronic circuit to dissipate a waste heat generated by a heat generating element, which is calibrated at a proper orientation of heat dissipation, and which is provided with a heat absorption end and a heat sink end with the heat absorption end being acted on a heating end of the heat generating element, comprising an L-shape rigid heat pipe, an end of which is a heat release end for assembling a fin to constitute the heat sink end, and the other end of which is a bare tube heating end; as well as a heat absorption head and a clip board, which clip the aforementioned heating end through a fixing element to form the heat absorption end.

2. The heat sink device for a heat generating element according to claim 1, wherein the clip board is provided with a concave rest having a positioning notch, at a location corresponding to the heating end.

3. The heat sink device for a heat generating element according to claim 1, wherein a cross rest is installed on an opposite surface of the heat absorption head.

4. The heat sink device for a heat generating element according to claim 2, wherein more than two parallel concave rests are provided.

5. The heat sink device for a heat generating element according to claim 2, wherein the concave rests are staggered in a cross shape.

6. The heat sink device for a heat generating element according to claim 3, wherein more than two parallel cross rests are provided.

7. The heat sink device for a heat generating element according to claim 3, wherein the cross rests are staggered in a cross shape.

8. The heat sink device for a heat generating element according to claim 2, wherein the notch is formed by a plurality of projected items which are aligned in a matrix and are protruded on a surface of the clip board corresponding to the heat absorption head.

9. The heat sink device for a heat generating element according to claim 1, wherein a relative gap between the heat absorption head and the heating end of heat pipe which is clipped by the clip board can be filled with a heat conduction glue.

10. The heat sink device for a heat generating element according to claim 1, wherein the clip board and the heat absorption head can clip more than one heat pipe at the same time.

11. The heat sink device for a heat generating element according to claim 1, wherein the cooling fin at the heat sink end is provided with at least one flat and smooth diversion side to assemble with a diversion device.

12. The heat sink device for a heat generating element according to claim 1, wherein the fixing element is an elastic hook.
